(19) United States
(12) Patent Application Publication
(10) Pub. No.: US 2025/0116736 A1
(43) Pub. Date: Apr. 10, 2025

(54) DATA PROCESSING METHOD, RECORDING MEDIUM, AND DATA PROCESSING SYSTEM

(71) Applicant: SHIMADZU CORPORATION, Kyoto-shi (JP)

(72) Inventor: Tomoaki TSUDA, Kyoto-shi (JP)

(21) Appl. No.: 18/907,148

(22) Filed: Oct. 4, 2024

(30) Foreign Application Priority Data
Oct. 10, 2023 (JP) 2023-174947

(51) Int. Cl. G01R 33/10; G01R 33/00

(52) U.S. Cl. CPC G01R 33/10; G01R 33/0017

(57) ABSTRACT

A data processing method acquires an output value of a magnetic field from each of one or more magnetic sensors and identifies, for each of the one or more magnetic sensors, the magnetic field resulting from the position at which the output value was derived. The data processing method generates a detection value for each of the one or more magnetic sensors by removing the magnetic field resulting from the position from the output value.

### CROSS-REFERENCE TO RELATED APPLICATIONS

This application claims priority under 35 U.S.C. § 119 to Japanese Patent Application No. 2023-174947 filed on Oct. 10, 2023, the entire disclosure of which is incorporated herein by reference in its entirety.

### BACKGROUND OF THE INVENTION

### Field of the Invention

The present disclosure relates to data processing of a portable magnetic sensor.

### Description of the Related Art

The following description sets forth the inventor's knowledge of the related art and problems therein and should not be construed as an admission of knowledge in the prior art.

There is a known technique for detecting activities inside a living body using a plurality of electromagnetic sensors arranged on the surface of the subject's living body. For example, the brain magnetic field is measured by a plurality of sensors arranged on the subject's head, a magnetoencephalography (MEG) is generated using the measured brain magnetic field, and biological activities are estimated by analyzing the magnetoencephalography.

Conventionally, brain magnetic fields have been measured using a system equipped with a plurality of superconducting quantum interference device (SQUID) sensors, each requiring cooling with liquid helium. Each SQUID sensor is secured in a dewar filled with liquid helium. The dewar contains 100 to 300 SQUID sensors and has a recess in a helmet for fitting a head. When measuring, it is required to align the position of each SQUID sensor in the dewar with the position of the head. For this reason, the head is fixed while being fitted in the recess. During the measurement, the subject was unable to move their head and trunk and experienced discomfort and fatigue, which posed a problem.

In recent years, extensive development has been carried out on compact, portable magnetic sensors that can operate at room temperature. Because magnetic sensors operate at room temperature, cooling with liquid helium is not required to measure brain magnetic fields. Therefore, when such sensors are used, as long as the sensors are secured to the helmet, measurements can be performed without restraining the head wearing the helmet. Regarding measurements of brain magnetic fields using portable magnetic sensors as described above, various studies have been conducted, as disclosed, for example, in Japanese Unexamined Patent Application Publication No. 2020-151023 and Ryan M. Hill, et. al, “Multi-channel whole-head OPM-MEG: Helmet design and a comparison with a conventional system,” Neuroimage, Oct. 1, 2020.

The operating magnetic field range of a portable magnetic sensor is relatively narrow, such as about 50 nT or less. For this reason, like conventional measurements using SQUID sensors, measurements using portable magnetic sensors require a magnetic shield room. Further, in measurements using portable magnetic sensors, it is necessary to make the magnetic field in the measurement area uniform by using planar coils or other components to allow for the subject's movements (in the case of measuring brain magnetic fields, head movements).

However, it is difficult to create a perfectly uniform magnetic field. Therefore, it can be assumed that factors causing changes in the signals output from portable magnetic sensors include not only changes in the actual magnetic field at the subject but also changes in the background magnetic fields resulting from swaying. Under these circumstances, there is a need for a technique to accurately measure the changes in the magnetic field within the subject when measuring the magnetic field using portable magnetic sensors.

### SUMMARY OF THE INVENTION

The preferred embodiments of the present disclosure have been developed in view of the above-mentioned and/or other problems in the related art. The preferred embodiments of the present disclosure can significantly improve upon existing methods and/or apparatuses.

The present disclosure has been conceived in view of these circumstances, and the purpose of the present disclosure is to provide a technique for accurately measuring changes in the magnetic field within a subject when measuring the magnetic field using portable magnetic sensors.

A data processing method according to one aspect of the present disclosure is a data processing method for one or more portable magnetic sensors arranged in a predetermined arrangement, comprising:
a step of acquiring an output value of a magnetic field from each of the one or more magnetic sensors;
a step of identifying, for each of the one or more magnetic sensors, a magnetic field resulting from a position when the output value is derived; and
a step of generating, for each of the one or more magnetic sensors, a detection value by removing the magnetic field resulting from the position from the output value.

The above and/or other aspects, features and/or advantages of various embodiments will be further appreciated in view of the following description in conjunction with the accompanying figures. Various embodiments can include and/or exclude different aspects, features and/or advantages where applicable. In addition, various embodiments can combine one or more aspects or features of other embodiments where applicable. The descriptions of aspects, features and/or advantages of particular embodiments should not be construed as limiting other embodiments or the claims.

### BRIEF DESCRIPTION OF THE DRAWINGS

The preferred embodiments of the present disclosure are shown by way of example, and not limitation, in the accompanying figures.

FIG. 1 is a schematic diagram showing the overall structure of the data processing system 1 for portable magnetic sensors.

FIG. 2 is a diagram showing the configuration of the helmet 20.

FIG. 3 is a perspective view schematically showing the interior of a magnetic shield room.

FIG. 4 is a front view schematically showing the interior of the magnetic shield room.

FIG. 5 is a diagram schematically showing one example of a magnetic field distribution in a measurement area 40.

FIG. 6 is a diagram showing one example of the state of a helmet 20 in the measurement area 40.

FIG. 7 is a diagram showing another example of the state of the helmet 20 in the measurement area 40.

FIG. 8 is a diagram showing a specific example of the output value and the detection value of an OPM sensor 2.

FIG. 9 is a flowchart of the processing carried out in the data processing system 1 for generating magnetoencephalography.

FIG. 10 is a flowchart of a modification of the processing in FIG. 9.

### DETAILED DESCRIPTION OF THE PREFERRED EMBODIMENTS

In the following paragraphs, some preferred embodiments of the present disclosure will be described by way of example and not limitation. It should be understood based on this disclosure that various other modifications can be made by those skilled in the art based on these illustrated embodiments.

Note that the same or equivalent part in the figures is assigned by the same reference symbol, and the description will not be repeated.

### Embodiment 1

### [Configuration of Data Processing System]

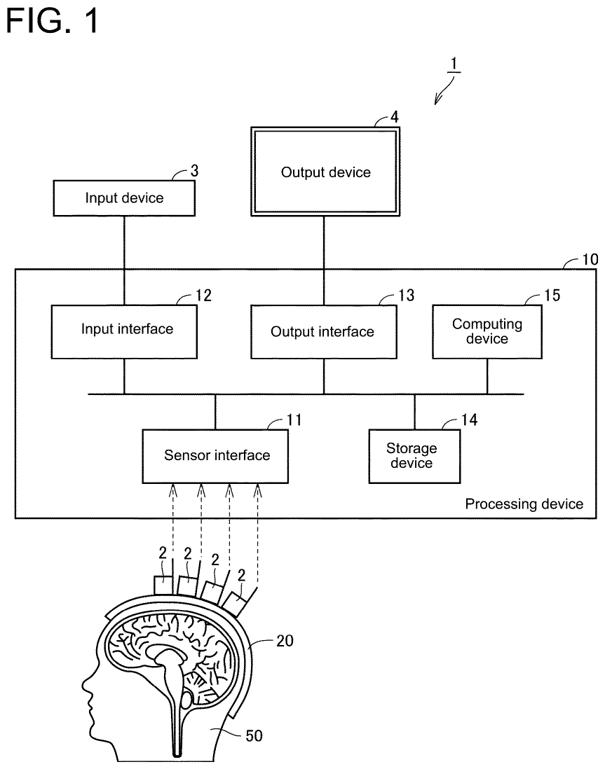

FIG. 1 is a diagram schematically showing the overall structure of the data processing system 1 for portable magnetic sensors. In this embodiment, as one example of the portable magnetic sensor, the case of using an OPM (Optically Pumped Magnetometer) sensor 2, which is a compact magnetic sensor that operates at room temperature, will be described. As a portable magnetic sensor, in addition to an OPM sensor, a fluxgate sensor, a tunnel magnetoresistance effect (TMR) sensor, and a giant magnetoresistance effect (GMR) sensor are exemplified. Further, in this embodiment, although the measurement of magnetoencephalography is described as an example, the measurement target is not limited to magnetoencephalography, but can also be something else (magnetocardiography).

The data processing system 1 is equipped with a plurality of OPM sensors 2, an input device 3, an output device 4, and a processing device 10. The data processing system 1 is configured to estimate the positions of biological activity locations (current sources) in the subject's brain using detection results from the plurality of OPM sensors 2.

Each of the plurality of OPM sensors 2 is mounted on a helmet 20. As the subject 50 wears the helmet 20 on his/her head, each of the plurality of OPM sensors 2 is positioned on the head of the subject 50 in a predetermined arrangement. In FIG. 1, for convenience of explanation, the number of OPM sensors 2 shown is “4,” but the number of OPM sensors 2 used for measurement is not limited to this number.

The input device 3 is a pointing device, such as a keyboard and a mouse, and accepts input information (such as calculation conditions described below) from the user. The information input to the input device 3 is sent to the processing device 10. The output device 4 is configured, for example, by a liquid crystal display (LCD) panel and is a display that shows information to the user.

The processing device 10 is equipped with a sensor interface 11, an input interface 12, an output interface 13, a storage device 14, and a computing device 15, as main hardware elements. Note that the processing device 10 may be realized, for example, by a general-purpose computer or by a computer (e.g., server) dedicated to the data processing system 1.

The sensor interface 11 is an interface for connecting the processing device 10 to the plurality of OPM sensors 2 and enables inputting and outputting of signals between the processing device 10 and the plurality of OPM sensors 2. The input interface 12 is an interface for connecting the input device 3 to the processing device 10 and enables inputting and outputting of signals between the processing device 10 and the input device 3. The output interface 13 is an interface for connecting the output device 4 to the processing device 10 and enables data inputting and outputting between the processing device 10 and the output device 4.

The storage device 14 non-transiently stores information (programs, etc.) used in the processing by the computing device 15. Note that the input information (such as the calculation conditions described below) input by the user to the input device 3 is stored in the storage device 14.

### [Helmet]

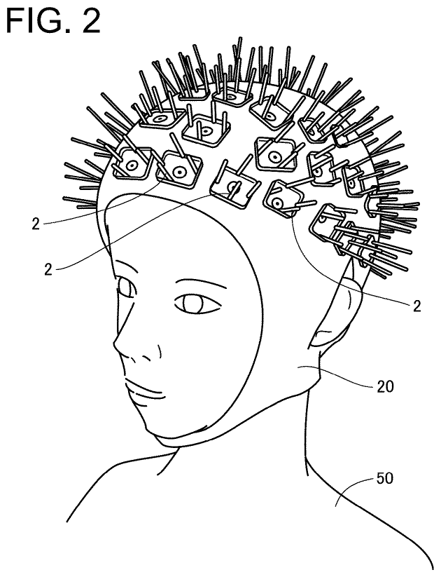

FIG. 2 is a diagram showing the configuration of the helmet 20. A plurality of OPM sensors 2 is mounted on the helmet 20. In one embodiment, the arrangement of the plurality of OPM sensors 2 is fixed on the helmet 20.

### [Measurement Environment]

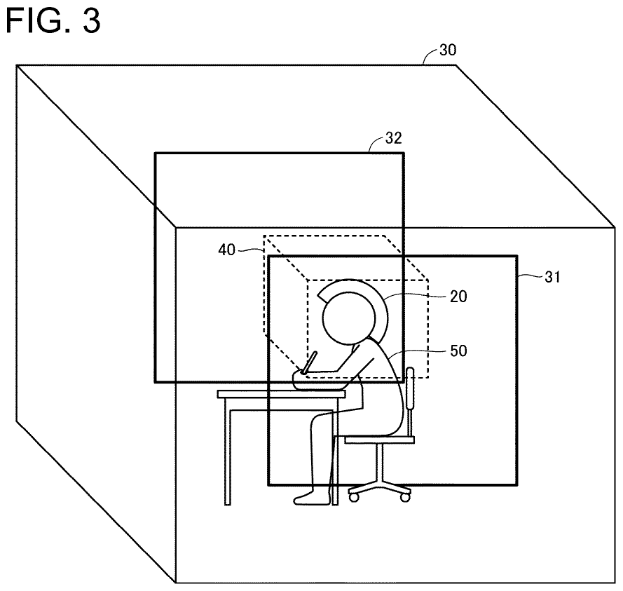

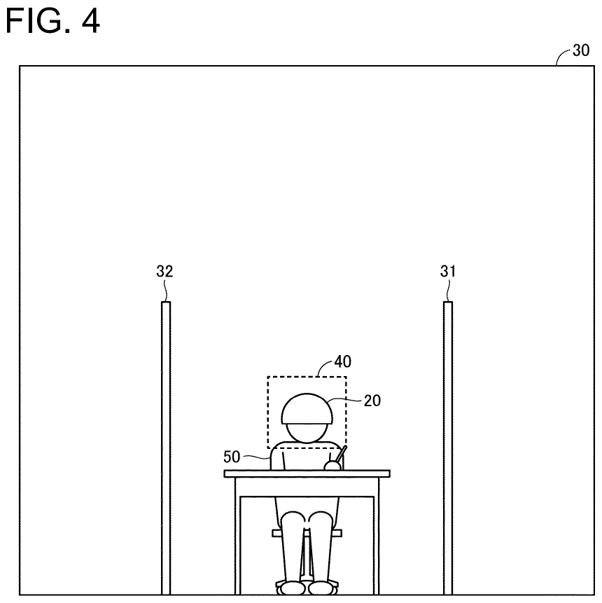

FIG. 3 is a perspective view schematically showing the interior of a magnetic shield room. FIG. 4 is a front view schematically showing the interior of the magnetic shield room.

The measurement of the brain magnetic field is performed in a magnetic shield room 30. In the magnetic shield room 30, on one side and the other side of the subject 50, a board 31 and a board 32, each having a planar coil for noise cancellation, are placed, respectively.

In the magnetic shield room 30, a measurement area 40 is defined as the area where the head of the subject 50 is expected to be positioned. The measurement area 40 is, for example, a rectangular prism with dimensions of 40 cm by 40 cm. However, there is no particular limit to the size of the measurement area 40.

### [Spatial Magnetic Field Distribution]

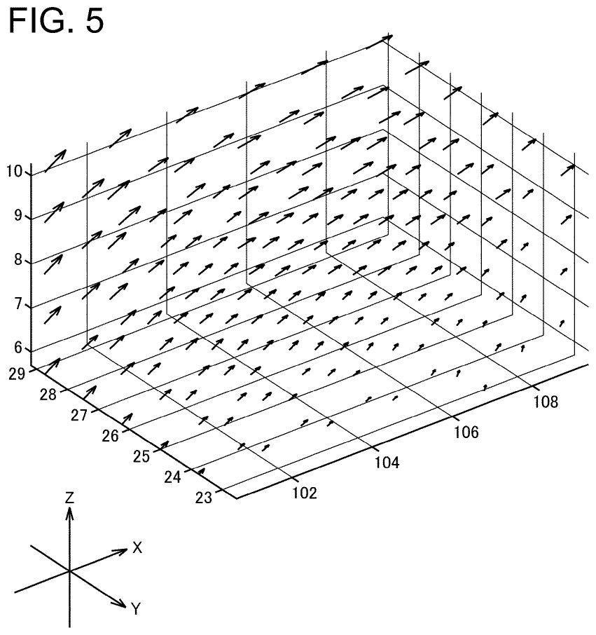

FIG. 5 is a diagram schematically showing one example of the magnetic field distribution in the measurement area 40. FIG. 5 shows pre-measured magnetic fields for each of a plurality of locations in the measurement area 40, indicated by arrows. The direction of the arrow represents the direction of the magnetic field in three-dimensional space defined by the three axes (X-, Y-, and Z-axes). The length of the arrow indicates the magnitude of the magnetic field. The direction and magnitude of the magnetic field at each of the plurality of locations in the measurement area 40 are stored, for example, in the storage device 14 as a “spatial magnetic field distribution.” In one example, as a “spatial magnetic field distribution,” the magnetic fields of 125 locations positioned at 10 cm intervals are stored for a 40 cm square space.

In one example, the magnetic field at each of the plurality of locations in the measurement area 40 is measured in a state in which the subject is not present in the magnetic shield room 30. The computing device 15 generates a spatial magnetic field distribution based on the measurement results, and the generated spatial magnetic field distribution is stored in the storage device 14.

### [Background Magnetic Field]

The data processing system 1 generates the magnetoencephalography of the subject 50 based on the detection values of each of the plurality of OPM sensors 2. Note that in some cases, the position of each OPM sensor 2 may change during the measurement of the brain magnetic field. For each OPM sensor 2, the data processing system 1 identifies the background magnetic field resulting from the position and subtracts the background magnetic field from the output value to produce a detection value.

More specifically, when the data processing system 1 obtains the output value from each OPM sensor 2, it generates a detection value from the output value for each OPM sensor 2. This generates detection values for the plurality of OPM sensors 2. The data processing system 1 then generates the magnetoencephalography using the detection values generated for the plurality of OPM sensors 2. Hereafter, the change in the position of the OPM sensor 2, the identification of the background magnetic field resulting from the position, and the derivation of the detection value will be explained in more detail.

### (Change in Position of OPM Sensor 2)

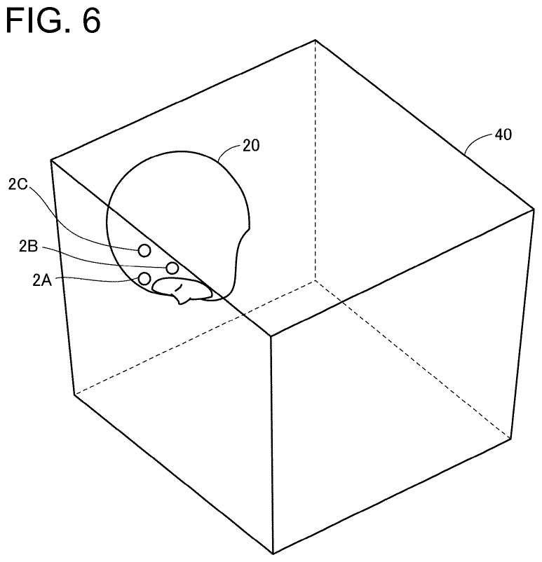

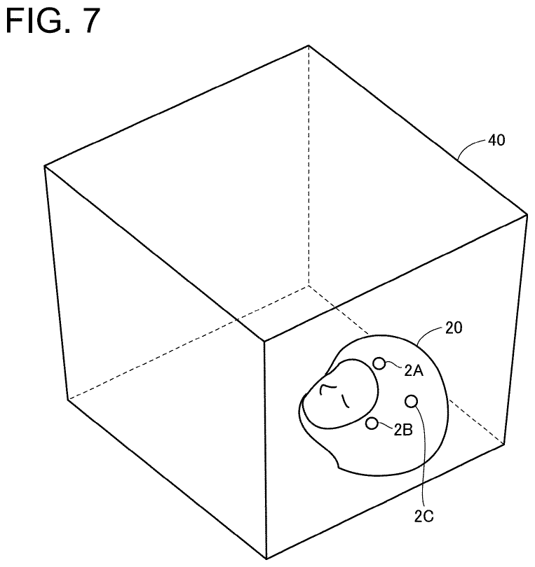

In the data processing system 1, the helmet 20 may move in accordance with the movements of the head of the subject 50, causing the position of each OPM sensor 2 to change. FIG. 6 is a diagram showing one example of the state of the helmet 20 in the measurement area 40. FIG. 7 is a diagram showing another example of the state of the helmet 20 in the measurement area 40. In FIG. 6 and FIG. 7, three OPM sensors 2 out of the plurality of OPM sensors 2 are shown as OPM sensors 2A, 2B, and 2C for the sake of explanation.

As shown in FIG. 6 and FIG. 7, when the head of the subject 50 wearing the helmet 20 moves, the position and posture of the helmet 20 changes. More specifically, in FIG. 6, the helmet 20 is positioned in the upper left of the measurement area 40, whereas in FIG. 7, the helmet 20 is positioned in the lower right of the measurement area 40.

Further, between FIG. 6 and FIG. 7, the posture of the helmet 20 changes, which changes the positional relation between the OPM sensors 2A, 2B, and 2C. More specifically, the OPM sensor 2A is positioned lower left relative to the OPM sensor 2B and the OPM sensor 2C in FIG. 6, whereas it is positioned upper right relative to the OPM sensor 2B and the OPM sensor 2C in FIG. 7.

### (Identification of Background Magnetic Field for Each OMP Sensor 2)

While the geomagnetic field is in the range of several microteslas (μT), the changes in the brain magnetic field occur in the range of several femtoteslas (fT). Even if the magnetoencephalography measurement is performed in the magnetic shield room 30, it is difficult to keep the magnetic field in the magnetic shield room 30 constant enough not to affect the brain magnetic field. From this, it is assumed that as the position of the OPM sensor 2 changes, the magnitude of the background magnetic field contained in the output value of the OPM sensor 2 will change. Therefore, if the output values of the OPM sensors 2 are used as detection values as they are in the generation of the magnetoencephalography, the magnetoencephalography may lack accuracy.

The data processing system 1 identifies the location within the measurement area 40 of each OPM sensor 2. The data processing system 1 identifies the magnetic field at the identified location among the magnetic fields at a plurality of locations within the measurement area 40 that are registered as a spatial magnetic field distribution, as the background magnetic field for each OPM sensor 2. For example, in the case where the magnetic fields of 125 locations are registered as a spatial magnetic field distribution, and 20 OPM sensors 2 are attached to the helmet 20, the data processing system 1 will identify the magnetic field of the location corresponding to each of the 20 OPM sensors 2 from among the magnetic fields of the 125 locations as the background magnetic field for each OPM sensor 2.

In one example realization, the data processing system 1 uses a maximum likelihood estimation to identify the background magnetic field of each OPM sensor 2.

More specifically, the data processing system 1 obtains output values from a first number of OPM sensors 2. With this, the data processing system 1 obtains the first number of output values. The data processing system 1 arranges the first number of output values according to the arrangement of the first number of OPM sensors 2 on the helmet 20.

In the spatial magnetic field distribution, it is assumed that magnetic fields of a second number of locations (greater than the first number) are registered.

The data processing system 1 searches for a combination of the magnetic fields at the first number of locations that correspond to the first number of output values arranged as described above, among the magnetic fields at the second number of locations that constitute the spatial magnetic field distribution. For this search, maximum likelihood estimation is used. In the maximum likelihood estimation, the likelihood function is defined as shown in the following Equations (1) and (2).

$$\begin{matrix} \\ \begin{matrix}\vec{y} mv ⋆ ( t ) = \\ {}^{⋆} measured value\end{matrix}\end{matrix} {[ \begin{matrix}{f}_{sx} & {f}_{sy} & {f}_{sz} \\ & ⋮ & \\ & & \end{matrix} ]}^{\begin{matrix}x & y & z\end{matrix}} \begin{matrix}sensor = 1 \\ ⋮ \\ sensor = n\end{matrix} \qquad ( 1 )$$

$$Space in FIG . 5 : G$$

$$\begin{matrix} \\ V ( t ) = G ( x , y , z , θ x , θ y , θ z ) = \\ ( six degree of freedom )\end{matrix} {[ \begin{matrix}{g}_{sx} & {g}_{sy} & {g}_{sz} \\ & ⋮ & \\ & & \end{matrix} ]}^{\begin{matrix}x & y & z\end{matrix}} \begin{matrix}sensor = 1 \\ ⋮ \\ sensor = n\end{matrix} \qquad ( 2 )$$

In Equations (1) and (2), each OPM sensor 2 is shown as sensor=1 to n. Equation (1) represents a measured value y obtained from each magnetic sensor. In Equation (1), the measured values of the magnetism of each OPM sensor 2 in each of the three axes are shown as fsx, fsy, and fsz. Equation (2) represents the magnetic field V at any sensor arrangement in the magnetic field space G. In Equation (2), the measured value of the magnetic field of each OPM sensor 2 at the coordinates (x, y, z) in the magnetic field space G is shown as fgx, fgy, fgz. The position of the helmet (head), which changes over time due to head movements and other factors, or the background magnetic field of each OPM sensor, is determined by the minimum squared error between the measured value y and the magnetic field V.

The data processing system 1 selects a combination of the first number of magnetic fields having the largest value of the likelihood function among the magnetic fields of the second number of locations registered as a spatial magnetic field distribution, as a combination of magnetic fields corresponding to the combination of the first number of OPM sensors 2.

The data processing system 1 decomposes the combination of the first number of magnetic fields selected from the spatial magnetic field distribution into a background magnetic field for each OPM sensor 2 according to the arrangements of the multiple OPM sensors 2 on the helmet 20.

For example, in the case where 20 OPM sensors 2 are mounted on the helmet 20, and brain magnetic fields corresponding to biological activities are generated at the positions corresponding to 4 of the 20 OPM sensors 2, and no brain magnetic fields corresponding to biological activities are generated at the positions corresponding to the remaining 16 OPM sensors 2, the output values of the 16 OPM sensors 2 should match the values of the background magnetic fields. From this, by the maximum likelihood estimation using the likelihood function shown in Equation (1), the combination of the background magnetic fields of the 20 OPM sensors 2 can be selected from the plurality of magnetic field combinations registered as spatial magnetic field distributions by using the combination of the output values of the 20 OPM sensors 2 on the helmet 20.

In the data processing system 1, as a spatial magnetic field distribution, a magnetic field for each of the plurality of locations in the measurement area 40 is stored. In other words, the data processing system 1 allows movements of the head of the subject 50 within the measurement area 40. The wider the range of the measurement area 40, the greater the range of acceptable head movements of the subject 50, but the greater the computational load in the maximum likelihood estimation. Therefore, the size of the measurement area 40 may be set based on the computational load allowed in the maximum likelihood estimation.

(Derivation of Detection value)

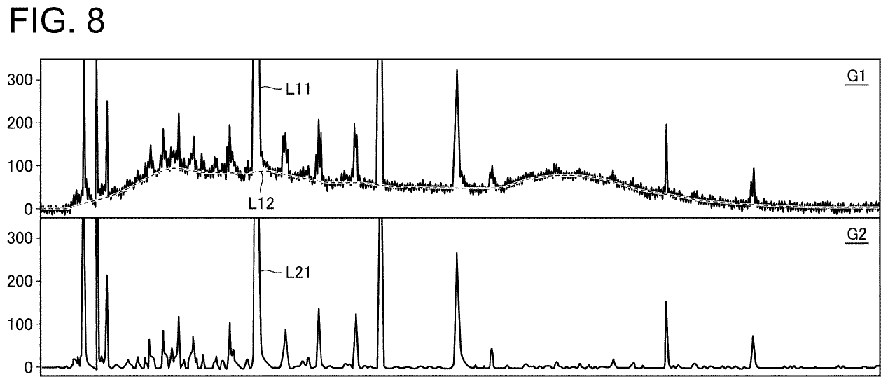

FIG. 8 is a diagram showing a specific example of the output value and the detection value of the OPM sensor 2. In FIG. 8, Graph G1 shows the output value as a line L11, and Graph G2 shows a line L21 as a detection value. In Graphs G1 and G2, the vertical axis represents the strength of the magnetic field, and the horizontal axis represents the time.

In Graph G1, the line L12 represents the background magnetic field. In the example in FIG. 8, the detection value represented by the line L21 is calculated by subtracting the value of the line L12 from the value of the line L11. In other words, the detection value corresponds to the value obtained by removing the background magnetic field from the output value.

### [Processing Flow]

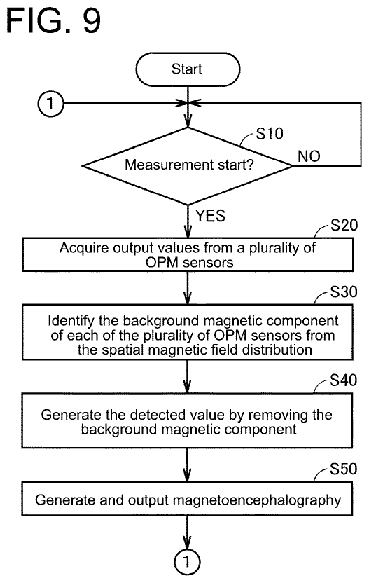

FIG. 9 is a flowchart of the processing carried out in the data processing system 1 for generating magnetoencephalography. In one example, in the processing device 10, the processing of FIG. 9 is realized by the computing device 15 executing a given program.

In Step S10, the computing device 15 determines whether the start of the measurement of magnetoencephalography is instructed. The instruction to start the measurement of magnetoencephalography may be input to the computing device 15 from the input device 3 or from an external device to the computing device 15 via a network. The computing device 15 repeats the control of Step S10 until it determines that the start of measurement is instructed (NO in Step S10), and when it determines that the start of measurement is instructed (YES in Step S10), it proceeds to Step S20.\

In Step S20, the computing device 15 acquires output values from the plurality of OPM sensors 2.

In Step S30, the computing device 15 identifies the background magnetic field component of each of the plurality of OPM sensors 2 from the spatial magnetic field distribution. In one example realization, the control of Step S30 follows the contents described above in [Identification of Background Magnetic Field].

In Step S40, the computing device 15 generates a detection value for each of the plurality of OPM sensors 2 by removing the background magnetic field from each of the output values of the plurality of OPM sensors 2.

In Step S50, the computing device 15 generates magnetoencephalography using the detection value of each of the plurality of OPM sensors 2 and outputs the magnetoencephalography. The output of the magnetoencephalography is, for example, displayed on the output device 4. Thereafter, the computing device 15 returns the control to Step S10.

In Embodiment 1 described above, the computing device 15 generates the detection value of each of the plurality of OPM sensors 2 by removing the background magnetic field from the output value of each of the plurality of OPM sensors 2. Then, the computing device 15 generates magnetoencephalography using the detection values of each of the plurality of OPM sensors 2.

### Embodiment 2

The computing device 15 may perform a correction of the magnetic field at a plurality of locations registered as spatial magnetic field distributions.

Further, instead of being attached to a non-deforming component such as a helmet, the plurality of OPM sensors 2 may be attached to a deformable component such as headgear. In such a case, the computing device 15 may perform a control to identify the arrangement of the plurality of OPM sensors 2 on the head of the subject 50 wearing the headgear.

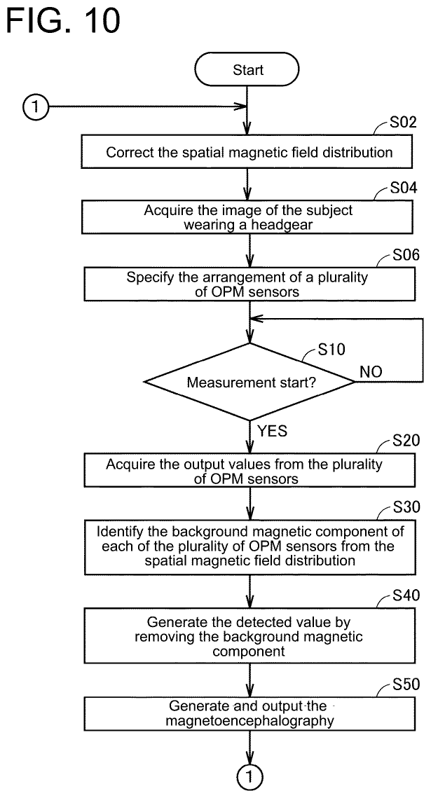

FIG. 10 is a flowchart of a modification of the processing in FIG. 9. The processing in FIG. 10 further includes Steps S02, S04, and S06, as compared with the processing in FIG. 9.

Referring to FIG. 10, in Step S02, the computing device 15 corrects the spatial magnetic field distribution.

More specifically, the computing device 15 measures the magnetic field at one of the plurality of locations where a magnetic field is registered in the spatial magnetic field distribution. Further, the computing device 15 compares the measured magnetic field with the magnetic field registered in the spatial magnetic field distribution for the one location. The computing device 15 then adds the difference between the measured magnetic field and the registered magnetic field to the magnetic fields at all registered locations in the spatial magnetic field distribution. In other words, the computing device 15 detects the magnetic field at one location and corrects the magnetic field at both the one location and other locations contained in the spatial magnetic field distribution by using the detection results of the detection.

As the “one location” described above, it is preferred that a location where the OPM sensor 2 is unlikely to be positioned in the measurement of the magnetoencephalography be selected among the plurality of locations defined in the measurement area 40. Note that detection values of magnetic fields at two or more locations may be used for the correction.

In Step S04, the computing device 15 acquires an image (e.g., a 3D image) of the subject wearing the headgear.

In Step S06, the computing device 15 identifies the arrangement of the plurality of OPM sensors 2 on the subject's head by analyzing the image acquired in Step S04. In one example realization, the analysis of the image identifies the portion of the image corresponding to each of the plurality of OPM sensors 2 and identifies the arrangement of the plurality of OPM sensors 2 on the subject's head based on the arrangement of the portions of each OPM sensor 2. Thereafter, the computing device 15 proceeds with the control to Step S10.

According to the processing described with reference to FIG. 10, the magnetic fields at a plurality of locations that constitute the spatial magnetic field distribution are corrected accordingly. The correction of the spatial magnetic field distribution ensures the accuracy of the value used as the background magnetic field, which in turn can ensure the accuracy of the detection value of the magnetic field.

In the processing described with reference to FIG. 10, even in the case where the subject 50 wears a member utilizing flexible material, such as a headgear, instead of a helmet 20, the data processing system 1 can recognize the arrangement of the multiple OPM sensors 2 and use it to generate the detection values. This allows a variety of embodiments in which the subject 50 can wear a plurality of OPM sensors 2.

The timing (or conditions) for performing each of the correction of the spatial magnetic field distribution in Step S02 and/or the identification of the positions of the plurality of OPM sensors 2 in Steps S04 and S06 can be set as appropriate. For example, in the case where a plurality of magnetoencephalograph is measured consecutively for the same subject 50, the correction of the spatial magnetic field distribution in Step S02 and/or the identification of the positions of the plurality of OPM sensors 2 in Steps S04 and S06 may be performed for each magnetoencephalography measurement, or may be performed only once before the measurement of the plurality of magnetoencephalograph.

### Aspects

It would be understood by those skilled in the art that the exemplary embodiments described above are specific examples of the following aspects.

### (Item 1)

A data processing method according to one embodiment is a data processing method for one or more portable magnetic sensors arranged in a predetermined arrangement. It may be configured to include:
a step of acquiring an output value of a magnetic field from each of the one or more magnetic sensors;
a step of identifying, for each of the one or more magnetic sensors, a magnetic field resulting from a position when the output value is derived; and
a step of generating, for each of the one or more magnetic sensors, a detection value by removing the magnetic field resulting from the position from the output value.

According to the data processing method as recited in the above-described Item 1, a technique for accurately measuring changes in the magnetic field in a subject when measuring magnetic fields using magnetic sensors is provided.

### (Item 2)

In the data processing method as recited in the above-described Item 1, it may be configured such that
the one or more magnetic sensors derive the output value in a measurement area, and a magnetic field distribution is identified with respect to the measurement area, and
identifying the magnetic field resulting from the position includes
identifying, from the magnetic field distribution in the measurement area, a combination of magnetic fields corresponding to a combination of output values of the one or more magnetic sensors, and
identifying, from the identified combination of the magnetic fields, a magnetic field corresponding to the position of each of the one or more magnetic sensors.

According to the data processing method as recited in the above-described Item 2, the magnetic field distribution of the measurement area can be used as the magnetic field corresponding to each position of the one or more magnetic sensors.

### (Item 3)

In the data processing method as recited in the above-described Item 2, it may be configured such that identifying the combination of the magnetic fields includes
calculating, for each of a plurality of combinations of magnetic fields according to the predetermined arrangement, a value of a likelihood function indicating that each combination is a combination of the output values of the one or more of magnetic sensors, and
identifying a combination in which the value of the likelihood function becomes maximum, from among the plurality of combinations.

According to the data processing method as recited in the above-described Item 3, an appropriate magnetic field can be selected for each position of one or more magnetic sensors from a plurality of magnetic fields constituting the magnetic field distribution of the measurement area.

### (Item 4)

In the data processing method as recited in the above-described Item 3, it may be configured such that the data processing method further includes:
a step of measuring a magnetic field at at least one point in the measurement area; and
a step of correcting the magnetic field distribution, based on the magnetic field at the at least one point.

According to the data processing method as recited in the above-described Item 4, a more accurate value can be used as the magnetic field corresponding to each position of one or more magnetic sensors by correcting the magnetic field distribution in the measurement area.

### (Item 5)

In the data processing method as recited in any one of the above-described Items 1 to 4, it may be configured such that the data processing method further includes:
a step of acquiring position information on each of the one or more magnetic sensors in a state in which the one or more magnetic sensors are attached to the subject; and
a step of identifying the predetermined arrangement, based on the position information on each of the one or more magnetic sensors.

According to the data processing method as recited in the above-described Item 5, a variety of embodiments may be acceptable as a manner in which the subject wears one or more magnetic sensors.

### (Item 6)

A program according to one aspect of the present disclosure may be configured to, when executed by one or more processors of a computer, make the computer execute the data processing method as recited in any one of the above-described Items 1 to 5.

According to the program as recited in the above-described Item 6, when measuring the magnetic field using a magnetic sensor, a technique for accurately measuring changes in the magnetic field in a subject is provided.

### (Item 7)

A data processing system according to one aspect of the present disclosure may be configured to include:
a computer; and
one or more portable magnetic sensors,
wherein the computer includes
one or more processors, and
the storage device for storing the program as recited in claim 6.

The data processing system as recited in the above-described Item 7 provides a technique for accurately measuring changes in the magnetic field in a subject when measuring the magnetic field using a magnetic sensor.

Note that the embodiments disclosed here should be considered illustrative and not restrictive in all respects. It should be noted that the scope of the present disclosure is indicated by claims and is intended to include all modifications within the meaning and scope of the claims and equivalents. Further, it is intended that each of the techniques in the embodiments may be implemented alone or, if necessary, in combination with other techniques in the embodiments if possible.

Although some embodiments of the present disclosure have been described, the embodiments disclosed here should be considered in all respects illustrative and not restrictive. It should be noted that the scope of the present disclosure is indicated by claims and is intended to include all modifications within the meaning and scope of the claims and equivalents.

1. A data processing method for one or more portable magnetic sensors arranged in a predetermined arrangement, comprising:
a step of acquiring an output value of a magnetic field from each of the one or more magnetic sensors;
a step of identifying, for each of the one or more magnetic sensors, a magnetic field resulting from a position when the output value is derived; and
a step of generating, for each of the one or more magnetic sensors, a detection value by removing the magnetic field resulting from the position from the output value.

2. The data processing method as recited in claim 1,
wherein the one or more magnetic sensors derive the output value in a measurement area, and a magnetic field distribution is identified with respect to the measurement area, and
wherein identifying the magnetic field resulting from the position includes
identifying, from the magnetic field distribution in the measurement area, a combination of magnetic fields corresponding to a combination of output values of the one or more magnetic sensors, and
identifying, from the identified combination of the magnetic fields, a magnetic field corresponding to the position of each of the one or more magnetic sensors.

3. The data processing method as recited in claim 2,
wherein identifying the combination of the magnetic fields includes
calculating, for each of a plurality of combinations of magnetic fields according to the predetermined arrangement, a value of a likelihood function indicating that each combination is a combination of the output values of the one or more of magnetic sensors, and
identifying a combination in which the value of the likelihood function becomes maximum, from among the plurality of combinations in the magnetic distribution.

4. The data processing method as recited in claim 3, further comprising:
a step of measuring a magnetic field at at least one point in the measurement area; and
a step of correcting the magnetic field distribution, based on the magnetic field at the at least one point.

5. The data processing method as recited in claim 1, further comprising:
a step of acquiring position information on each of the one or more magnetic sensors in a state in which the one or more magnetic sensors are attached to the subject; and
a step of identifying the predetermined arrangement, based on the position information on each of the one or more magnetic sensors.

6. A recording medium non-transiently storing a program which, when executed by one or more processors of a computer, makes the computer execute the data processing method as recited in claim 1.

7. A data processing system comprising:
a computer; and
one or more portable magnetic sensors,
wherein the computer includes
one or more processors, and
the recording medium as recited in claim 6.
